(19) United States
(12) Patent Application Publication
(10) Pub. No.: US 2025/0107111 A1
(43) Pub. Date: Mar. 27, 2025

(54) METHOD FOR FABRICATING MOS CAPACITOR BASED ON SONOS PROCESS

(71) Applicant: Shanghai Huali Integrated Circuit Corporation, Shanghai (CN)

(72) Inventor: Peng Zhao, Shanghai (CN)

(73) Assignee: Shanghai Huali Integrated Circuit Corporation, Shanghai (CN)

(21) Appl. No.: 18/754,412

(22) Filed: Jun. 26, 2024

(30) Foreign Application Priority Data
Sep. 26, 2023 (CN) 202311255818.3

(51) Int. Cl. H10B 99/00; H01L 29/66; H01L 29/94

(52) U.S. Cl. CPC H10B 99/22; H10D 1/047; H10D 1/66

(57) ABSTRACT

This application provides a method for fabricating an MOS capacitor based on a SONOS process, including: forming a gate oxide layer on the semiconductor structure, the gate oxide layer covering a SONOS unit region, an MOS capacitor region and other device regions; removing the gate oxide layer on the SONOS unit region and the MOS capacitor region; forming an ONO film layer on the SONOS unit region, the MOS capacitor region, and the gate oxide layer on the other device regions; and performing etching to remove the ONO film layer on the other device regions, and reserve the ONO film layer on the SONOS unit region and the MOS capacitor region. According to this application, the threshold voltage of the MOS capacitor itself is increased and the working voltage of the capacitor in the accumulation region is decreased, thus greatly improving the voltage withstand performance of the MOS capacitor.

### CROSS-REFERENCE TO RELATED APPLICATIONS

This application claims priority to Chinese patent application No. 202311255818.3, filed on Sep. 26, 2023, the disclosure of which is incorporated herein by reference in its entirety.

### TECHNICAL FIELD

This application relates to the field of semiconductor technology, and in particular to a method for fabricating a metal-oxide-semiconductor (MOS) capacitor based on a silicon-oxide-nitride-oxide-silicon (SONOS) process.

### BACKGROUND

The currently commonly used MOS capacitors, when operating in a sub threshold region, exhibit a rapid decrease in capacitance value, with a noticeable concave region observed from the capacitance C-V curve (the reason for the formation of the concave region in the C-V curve of the capacitor of the NMOS transistor is that when the gate voltage of the MOS transistor rises, the holes are gradually repelled, a depletion layer starts to form, the NMOS transistor enters weak inversion, at this time the NMOS is equivalent to two capacitors, the gate oxide layer and the depletion layer, connected in series, and the capacitance value decreases. As the depletion layer increases, the total capacitance value continues to decrease).

Due to the presence of the concave region of the capacitor, the MOS capacitor generally works in an accumulation region, so that the voltage between upper and lower electrode plates of the capacitor is unchangeable. If it needs to work in a strong inversion region, in order to avoid the concave region, the working voltage of the capacitor needs to be far away from a moderate inversion region. The insulation medium of the MOS capacitor uses thinner gate oxide, resulting in poor voltage withstanding performance of the MOS capacitor.

Therefore, it is necessary to provide a new method to solve the above problems.

### BRIEF SUMMARY

The present application provides a method for fabricating an MOS capacitor based on a SONOS process, which is used for solving the problems that the voltage between upper and lower electrode plates of the capacitor is unchangeable and the voltage withstanding performance of the MOS capacitor is poor in the existing technology.

The present application provides a method for fabricating an MOS capacitor based on a SONOS process, at least including:
step 1: providing a semiconductor structure, the semiconductor structure including a SONOS unit region, an MOS capacitor region, and other device regions;
step 2: forming a gate oxide layer on the semiconductor structure, the gate oxide layer covering the SONOS unit region, the MOS capacitor region and the other device regions;
step 3: removing the gate oxide layer on the SONOS unit region and the MOS capacitor region;
step 4: forming an ONO film layer on the SONOS unit region, the MOS capacitor region, and the gate oxide layer on the other device regions; and
step 5: performing etching to remove the ONO film layer on the other device regions and reserve the ONO film layer on the SONOS unit region and the MOS capacitor region.

Exemplarily, in step 1, the semiconductor structure includes a substrate and an N-type deep well located on the substrate; the N-type deep well is located in the SONOS unit region; a tunneling oxide layer is provided on the N-type deep well; above the tunneling oxide layer 14 is used to form an ONO film layer; on one side of the tunneling oxide layer are the other device regions; the other device regions include a core device region and an IO device region.

Exemplarily, in step 1, the core device region includes an N-type core device region and a P-type core device region; the IO device region includes an N-type IO device region and a P-type IO device region.

Exemplarily, in step 1, the N-type core device region includes a P-well of a core device located on the substrate; the P-type core device region includes an N-well of the core device located on the substrate; the N-type IO device region includes a P-well of an IO device located on the substrate; the P-type IO device region includes an N-well of the IO device located on the substrate; the N-type core device region, the P-type core device region, the N-type IO device region and the P-type IO device region are isolated from each other by using shallow trench isolation (STI).

Exemplarily, in step 1, the MOS capacitor region further includes an N-type capacitor region and a P-type capacitor region; the N-type capacitor region includes a P-well located on the substrate; the P-type capacitor region includes an N-well located on one side of the P-well on the substrate; the P-well and the N-well are isolated by using STI; above the P-well and the N-well are used to form an ONO film layer.

Exemplarily, in step 5, the ONO film layer on the SONOS unit region includes a first ONO film layer located on the tunneling oxide layer and a second ONO film layer located on the first ONO film layer.

Exemplarily, in step 5, a method of performing etching to remove the ONO film layer on the other device regions includes: forming an antireflective coating layer on the ONO film layer; forming a photoresist layer on the antireflective coating layer; then performing a photolithography process to form a photoresist pattern, and etching the ONO film layer by using the photoresist pattern to remove the ONO film layer located on the other device regions.

Exemplarily, the ONO film layer formed on the MOS capacitor region in step 4 is used for increasing the threshold voltage of the MOS capacitor and decreasing the working voltage of the MOS capacitor in an accumulation region when performing a writing operation on a SONOS capacitor, so as to improve the voltage withstanding performance of the MOS capacitor.

Exemplarily, the MOS capacitor is an NMOS capacitor, the ONO film layer formed on the MOS capacitor region in step 4 is used for changing the threshold voltage of the NMOS capacitor to a negative value when performing an erasing operation on the SONOS capacitor, so that the NMOS capacitor works in a strong inversion region and the voltage between upper and lower electrode plates is changeable.

As described above, the method for fabricating the MOS capacitor based on the SONOS process according to this application has the following beneficial effects: in the method according to this application, by reserving the ONO film layer on the MOS capacitor region and performing a writing operation on the SONOS capacitor based on the need, the threshold voltage of the MOS capacitor itself is increased and the working voltage of the capacitor in the accumulation region is decreased, thus greatly improving the voltage withstand performance of the MOS capacitor; by performing an erasing operation on the SONOS, when the MOS capacitor is NMOS capacitor, the threshold voltage of the NMOS capacitor is changed to a negative value, so that the NMOS capacitor can work in a strong inversion region and the voltage between upper and lower electrode plates is changeable.

### BRIEF DESCRIPTION OF THE DRAWINGS

FIG. 1 illustrates a schematic structural diagram of a SONOS unit and an MOS capacitor according to this application.

FIG. 2 illustrates a schematic of working voltage during NMOS writing operation according to this application.

FIG. 3 illustrates a schematic of working voltage during NMOS erasing operation according to this application.

FIG. 4 illustrates a flowchart of a method for fabricating an MOS capacitor based on a SONOS process according to this application.

### DETAILED DESCRIPTION OF THE EMBODIMENTS

The embodiments of this application will be described below through specific examples. Those skilled in the art can easily understand other advantages and effects of this application from the content disclosed in this description. This application may also be implemented or applied through other different specific embodiments. The details in this description may be modified or changed based on different perspectives and applications without departing from the spirit of this application.

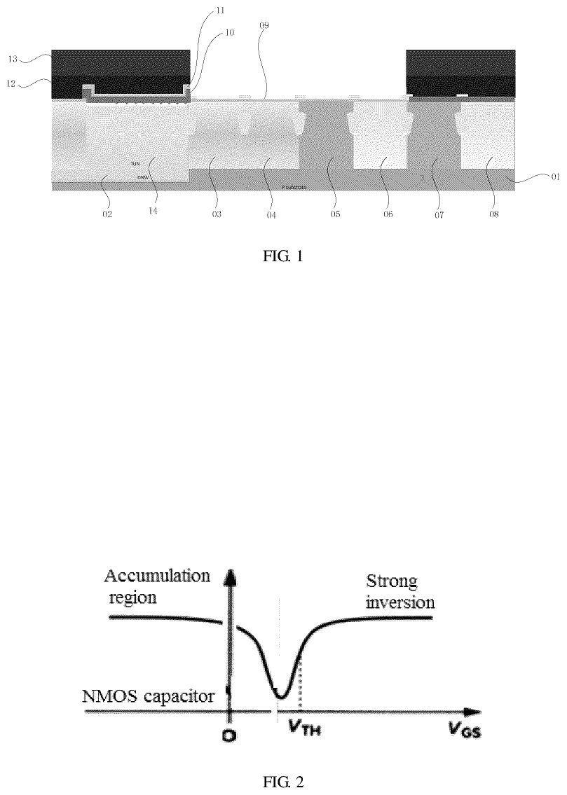

Please refer to FIG. 1 to FIG. 4. It should be noted that the drawings provided in the embodiments only schematically describe the basic concept of this application, only illustrate the components related to this application, and are not drawn according to the actual number, shape and size of the components during implementation. The type, number and scale of each component during actual implementation may be freely changed, and the layout of the component may be more complex.

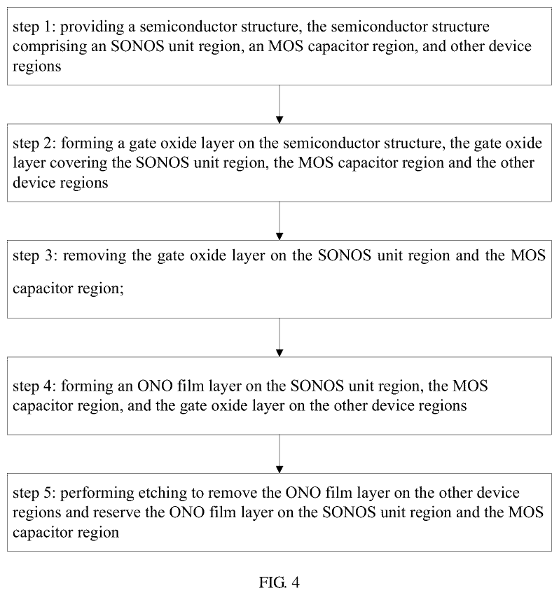

This application provides a method for fabricating an MOS capacitor based on a SONOS process. Referring to FIG. 4 which illustrates a flowchart of a method for fabricating an MOS capacitor based on a SONOS process according to this application, the method at least includes the following steps:

In step 1, a semiconductor structure is provided. The semiconductor structure includes a SONOS unit region, an MOS capacitor region, and other device regions.

Further, in this embodiment of this application, in step 1, the semiconductor structure includes a substrate and an N-type deep well located on the substrate; the N-type deep well is located in the SONOS unit region; a tunneling oxide layer is provided on the N-type deep well; above the tunneling oxide layer is used to form an ONO film layer; on one side of the tunneling oxide layer are the other device regions; the other device regions include a core device region and an IO device region.

Referring to FIG. 1 which illustrates a schematic structural diagram of a SONOS unit and an MOS capacitor according to this application, in step 1, the semiconductor structure includes a substrate 01 and an N-type deep well 02 located on the substrate 01; the N-type deep well 02 is located in the SONOS unit region; a tunneling oxide layer 14 is provided on the N-type deep well 02; above the tunneling oxide layer 14 is used to form an ONO film layer, and the ONO film layer located on the tunneling oxide layer 14 in this embodiment includes a first ONO film layer 10 and a second ONO film layer 11 on the first ONO film layer 10; on one side of the tunneling oxide layer 14 are the other device regions; the other device regions include a core device region and an IO device region.

Further, in this embodiment of this application, in step 1, the core device region includes an N-type core device region and a P-type core device region; the IO device region includes an N-type IO device region and a P-type IO device region.

Further, in this embodiment of this application, in step 1, the N-type core device region includes a P-well 03 of a core device located on the substrate 01; the P-type core device region includes an N-well 04 of the core device located on the substrate; the N-type IO device region includes a P-well 05 of an IO device located on the substrate; the P-type IO device region includes an N-well 06 of the IO device located on the substrate; the N-type core device region, the P-type core device region, the N-type IO device region and the P-type IO device region are isolated from each other by using STI.

Further, in this embodiment of this application, in step 1, the MOS capacitor region further includes an N-type capacitor region and a P-type capacitor region; the N-type capacitor region includes a P-well 07 located on the substrate 01; the P-type capacitor region includes an N-well 08 located on one side of the P-well 07 on the substrate; the P-well 07 and the N-well 08 are isolated by using STI; above the P-well 07 and the N-well 08 are used to form an ONO film layer.

In step 2, a gate oxide layer is formed on the semiconductor structure. The gate oxide layer covers the SONOS unit region, the MOS capacitor region and the other device regions. Specifically, in step 2, a gate oxide layer 09 is formed on the semiconductor structure. The gate oxide layer 09 covers the SONOS unit region, the MOS capacitor region and the other device regions.

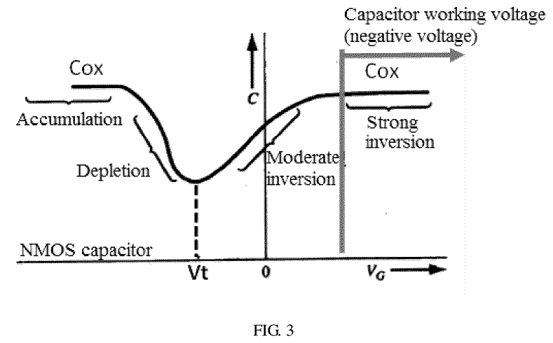

In step 3, the gate oxide layer on the SONOS unit region and the MOS capacitor region are removed. Specifically, referring to FIG. 3, in step 3, the gate oxide layer 09 on the SONOS unit region and the MOS capacitor region are removed, and the gate oxide layer 09 on the other device regions is only reserved.

In step 4, an ONO film layer is formed on the SONOS unit region, the MOS capacitor region, and the gate oxide layer on the other device regions.

In step 5, etching is performed to remove the ONO film layer on the other device regions and reserve the ONO film layer on the SONOS unit region and the MOS capacitor region.

Further, in this embodiment of this application, in step 5, the ONO film layer on the SONOS unit region includes a first ONO film layer 10 located on the tunneling oxide layer and a second ONO film layer 11 located on the first ONO film layer 10.

Further, in this embodiment of this application, in step 5, a method of performing etching to remove the ONO film layer on the other device regions includes: forming an antireflective coating layer on the ONO film layer; forming a photoresist layer on the antireflective coating layer; then performing a photolithography process to form a photoresist pattern 13, also forming a pattern 12 of the antireflective coating layer in this embodiment, and etching the ONO film layer by using the photoresist pattern 13 (also using the pattern 12 of the antireflective coating layer in this embodiment) to remove the ONO film layer located on the other device regions.

Further, in this embodiment of this application, the ONO film layer formed on the MOS capacitor region in step 4 is used for increasing the threshold voltage of the MOS capacitor and decreasing the working voltage of the MOS capacitor in an accumulation region when performing a writing operation on a SONOS capacitor, so as to improve the voltage withstanding performance of the MOS capacitor.

Further, in this embodiment of this application, the MOS capacitor is an NMOS capacitor, the ONO film layer formed on the MOS capacitor region in step 4 is used for changing the threshold voltage of the NMOS capacitor to a negative value when performing an erasing operation on the SONOS capacitor, so that the NMOS capacitor works in a strong inversion region and the voltage between upper and lower electrode plates is changeable.

The reason for the formation of the concave region in the C-V curve of the capacitor of the NMOS transistor is that when the gate voltage of the MOS transistor rises, the holes are gradually repelled, a depletion layer starts to form, the NMOS transistor enters weak inversion, at this time the NMOS is equivalent to two capacitors, the gate oxide layer and the depletion layer, connected in series, and the capacitance value decreases. As the depletion layer increases, the total capacitance value continues to decrease.

Therefore, in this application, by reserving the ONO film layer on the MOS capacitor region, the writing or erasing operation can be performed on the SONOS capacitor according to the need in use, so that the capacitor can achieve the required Vt.

Referring to FIG. 2 which illustrates a schematic of working voltage during NMOS writing operation according to this application, by performing the writing operation on SONOS, the Vt of the MOS capacitor is increased and the working voltage of the capacitor in the accumulation region is decreased (far away from the concave region of the capacitor in the depletion region), thus greatly improving the voltage withstanding performance of the MOS capacitor.

Referring to FIG. 3 which illustrates a schematic of working voltage during NMOS erasing operation according to this application, by performing the erasing operation on SONOS, the Vt of the NMOS capacitor is changed to a negative value, so that the NMOS can work in a strong inversion region, and the voltage between upper and lower electrode plates is changeable.

To sum up, in the method according to this application, by reserving the ONO film layer on the MOS capacitor region and performing a writing operation on the SONOS capacitor based on the need, the threshold voltage of the MOS capacitor itself is increased and the working voltage of the capacitor in the accumulation region is decreased, thus greatly improving the voltage withstand performance of the MOS capacitor; when the MOS capacitor is an NMOS capacitor, by performing an erasing operation on the SONOS, the threshold voltage of the NMOS capacitor is changed to a negative value, so that the NMOS capacitor can work in a strong inversion region and the voltage between upper and lower electrode plates is changeable. Therefore, this application effectively overcomes various disadvantages in the existing technology and thus has a great industrial utilization value.

The above embodiments only exemplarily describe the principle and effect of this application, and are not intended to limit this application. Those skilled in the art may modify or change the above embodiments without departing from the spirit and scope of this application. Therefore, all equivalent modifications or changes made by those skilled in the art without departing from the spirit and technical concept disclosed in this application should still be covered by the claims of this application.

What is claimed is:

1. A method for fabricating a metal-oxide-semiconductor (MOS) capacitor based on a silicon-oxide-nitride-oxide-silicon (SONOS) process, at least comprising:
step 1: providing a semiconductor structure, the semiconductor structure comprising a SONOS unit region, an MOS capacitor region, and other device regions;
step 2: forming a gate oxide layer on the semiconductor structure, the gate oxide layer covering the SONOS unit region, the MOS capacitor region, and the other device regions;
step 3: removing the gate oxide layer on the SONOS unit region and the MOS capacitor region;
step 4: forming an ONO film layer on the SONOS unit region, the MOS capacitor region, and the gate oxide layer on the other device regions; and
step 5: performing etching to remove the ONO film layer on the other device regions and reserve the ONO film layer on the SONOS unit region and the MOS capacitor region.

2. The method for fabricating the MOS capacitor based on the SONOS process according to claim 1, wherein in step 1, the semiconductor structure comprises a substrate and an N-type deep well located on the substrate; the N-type deep well is located in the SONOS unit region; a tunneling oxide layer is provided on the N-type deep well; above the tunneling oxide layer is used to form an ONO film layer; on one side of the tunneling oxide layer are the other device regions; and the other device regions comprise a core device region and an IO device region.

3. The method for fabricating the MOS capacitor based on the SONOS process according to claim 2, wherein in step 1, the core device region comprises an N-type core device region and a P-type core device region; and the IO device region comprises an N-type IO device region and a P-type IO device region.

4. The method for fabricating the MOS capacitor based on the SONOS process according to claim 3, wherein in step 1, the N-type core device region comprises a P-well of a core device located on the substrate; the P-type core device region comprises an N-well of the core device located on the substrate; the N-type IO device region comprises a P-well of an IO device located on the substrate; the P-type IO device region comprises an N-well of the IO device located on the substrate; and the N-type core device region, the P-type core device region, the N-type IO device region and the P-type IO device region are isolated from each other by using shallow trench isolation (STI).

5. The method for fabricating the MOS capacitor based on the SONOS process according to claim 1, wherein in step 1, the MOS capacitor region further comprises an N-type capacitor region and a P-type capacitor region; the N-type capacitor region comprises a P-well located on a substrate; the P-type capacitor region comprises an N-well located on one side of the P-well on the substrate; the P-well and the N-well are isolated by using STI;
and above the P-well and the N-well are used to form an ONO film layer.

6. The method for fabricating the MOS capacitor based on the SONOS process according to claim 2, wherein in step 5, the ONO film layer on the SONOS unit region comprises a first ONO film layer located on the tunneling oxide layer and a second ONO film layer located on the first ONO film layer.

7. The method for fabricating the MOS capacitor based on the SONOS process according to claim 1, wherein in step 5, a method of performing etching to remove the ONO film layer on the other device regions comprises:
forming an antireflective coating layer on the ONO film layer;
forming a photoresist layer on the antireflective coating layer; and
then performing a photolithography process to form a photoresist pattern, and etching the ONO film layer by using the photoresist pattern to remove the ONO film layer located on the other device regions.

8. The method for fabricating the MOS capacitor based on the SONOS process according to claim 1, wherein, the ONO film layer formed on the MOS capacitor region in step 4 is used for increasing a threshold voltage of the MOS capacitor and decreasing a working voltage of the MOS capacitor in an accumulation region when performing a writing operation on a SONOS capacitor, so as to improve a voltage withstanding performance of the MOS capacitor.

9. The method for fabricating the MOS capacitor based on the SONOS process according to claim 1, wherein, the MOS capacitor is an NMOS capacitor, the ONO film layer formed on the MOS capacitor region in step 4 is used for changing a threshold voltage of the NMOS capacitor to a negative value when performing an erasing operation on the SONOS capacitor, so that the NMOS capacitor works in a strong inversion region and a voltage between upper and lower electrode plates is changeable.
